(19) United States
(12) Patent Application Publication
(10) Pub. No.: US 2007/0096260 A1
(43) Pub. Date: May 3, 2007

(54) REDUCED PARASITIC AND HIGH VALUE RESISTOR AND METHOD OF MANUFACTURE

(75) Inventors: Ebenezer E. Eshun, Essex Junction, VT (US); Robert M. Rassel, Colchester, VT (US)

Correspondence Address: GREENBLUM & BERNSTEIN, P.L.C., 1950 ROLAND CLARK DRIVE, RESTON, VA, 20191, US

(73) Assignee: INTERNATIONAL BUSINESS MACHINES CORPORATION, Armonk, NY (US)

(21) Appl. No.: 11/163,741

(22) Filed: Oct. 28, 2005

(51) Int. Cl. H01L 27/082

(52) U.S. Cl. 257/581

(57) ABSTRACT

A method of manufacturing a device includes forming a dielectric layer on a substrate and forming a resistor on the dielectric layer. A second dielectric layer formed over the resistor is etched to expose edge portions of the resistor. The edge portions of the resistor are doped through the openings. A contact is formed in the openings. A device is also provided.

### FIELD OF THE INVENTION

The invention relates to semiconductor devices, and more particularly to an integration scheme for ohmic contact for a high value resistor and method of manufacture.

### BACKGROUND DESCRIPTION

High value polysilicon resistors are made over shallow trench isolation structure (STI) on the wafer surface. In normal processing, the resistors are made during front end of line processes (FEOL). As should be well understood, in FEOL, operations are performed on the semiconductor wafer in the course of device manufacturing up to first metallization. These operations are performed at temperatures higher than 600° C., which may result in some deleterious affects as discussed below.

As an illustration, in SOI-technology, a relatively thin layer of semiconductor material is used as a foundation to form active devices. Using such technology, integrated circuits are manufactured with a large number of electronic devices, such as resistors, transistors, diodes, and capacitors, many of which are manufactured in FEOL. These devices are typically electrically connected through interconnect structures such as, for example, wiring level local interconnects, buried contacts, studs, etc.

In forming a buried contact, a window is opened in a thin gate oxide over the active region. Polysilicon is deposited in direct contact with the active region in the opening, but is isolated from the underlying silicon of the active region by gate oxide and by field oxide, for example. An ohmic contact is formed at the interface between the polysilicon and the active region by diffusion into the active region of a dopant preset in the polysilicon, which effectively merges the polysilicon with the active region. A layer of insulating film is then deposited to cover the buried contact.

However, in such processes, it is difficult to align dopants with the to be formed active region, e.g., resistor, since the current fabrication steps are not self aligning. Also, the thermal cycles used in FEOL causes deactivation and activation fluctuations in the polysilicon resistor. These thermal cycles can also manipulate the morphology of the polysilicon film. This morphology, though, results in fluctuations in the resistance values of the resistor.

### SUMMARY OF THE INVENTION

In a first aspect of the invention, a method of manufacturing a device includes forming a dielectric layer on a substrate and forming a resistor on the dielectric layer. A second dielectric layer formed over the resistor is etched to expose edge portions of the resistor. The edge portions of the resistor are doped through the openings. A contact is formed in the openings.

In another aspect of the invention, the method of manufacturing includes providing a substrate having at least a wiring level in a first dielectric layer and forming a conductor layer on the first dielectric layer. The conductor layer is patterned to form end portions and a body portion. A second dielectric layer is formed over the patterned conductor layer. Openings are formed in the second dielectric layer substantially aligned with and exposing the end portions. An impurity region is formed in each of the end portions through the openings. A contact is formed in the openings coupled to the end portions to provide electrical connection to the body portion.

In yet another aspect of the invention, a structure includes a substrate having at least a wiring level formed in a first dielectric layer. A resistor is formed on the first dielectric layer having ends which are aligned with openings. An impurity region is provided in each of the end portions, which result in a higher dopant concentration than that of a middle portion of the resistor. The middle portion of the resistor maintains a high resistance value and the doped end portions are an ohmic contact. A contact is formed in each of the openings, which are coupled to the end portions to provide electrical connection to a wiring level.

### BRIEF DESCRIPTION OF THE DRAWINGS

FIGS. 1-6 illustrate steps in manufacturing a device in accordance with one embodiment of the invention;

FIGS. 6-11 illustrate steps in manufacturing a device in accordance with one embodiment of the invention; and

FIGS. 12-17 illustrate steps in manufacturing a device in accordance with one embodiment of the invention.

### DETAILED DESCRIPTION OF

Embodiments of the Invention

The invention is directed to high value BEOL (back end of line) resistors manufactured using a polysilicon film in BEOL levels. By moving the formation of the high value resistor to the BEOL, the distance from the substrate is increased resulting in a lower parasitic capacitance, e.g., ohmic-like contact. In the invention, the ohmic contact has a very low resistance independent of applied voltage. Also, by using the methods of the invention, low RC time constants are achieved to enhance circuit speeds. Additionally, by using the methods of the invention, the formation of the device during BEOL processes, which are typically run at temperatures lower than 600° C, it is possible to avoid changes in morphology of the polysilicon films which would result in fluctuations of the resistance values.

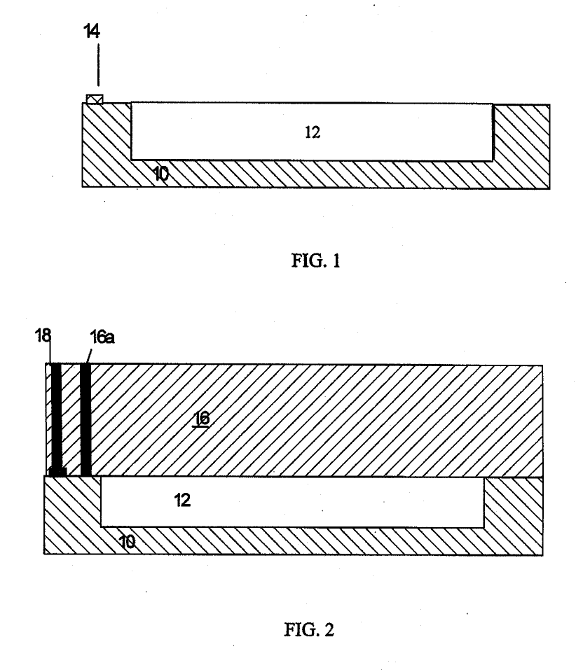

FIG. 1 shows a beginning structure in accordance with the invention. In this structure, an optional shallow trench isolation (STI) structure 12 formed in a wafer 10. The wafer may be formed from BOX, SOI or other conventional substrates. The STI 12 may be any material which provides a reduced parasitic capacitance such as, for example, oxide. A fully integrated device 14 may be formed on the wafer 10. Such a device may include, for example, a FET, a capacitor, a diode, etc.

FIG. 2 shows additional processing steps in accordance with the invention. In FIG. 2. a boro-phospho-silicate glass (BPSG) deposition process is performed using conventional methods such as chemical vapor deposition methods (CVD) to form layer 16. A conventional polishing process is performed to planarize the surface of the layer 16, which may be, as an example, a chemical mechanical polishing (CMP).

A conventional contact formation process is then used to form one or more contacts 18 (e.g., contact studs). For example, contact formation may include masking the layer 16 with a photoresist, exposing the photoresist and then etching the layer 16 to form a via 16a. The via 16a is then filled with a metal such as a tungsten to contact the substrate 10 or the active device 12. The photoresist may then be stripped from the layer 16 and an annealing process performed to passivate the contact studs 18.

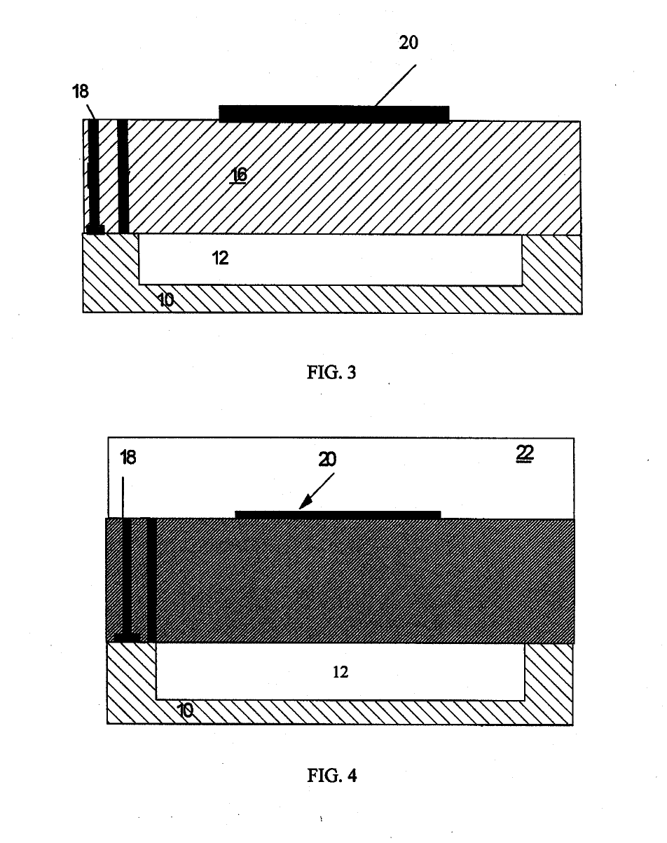

In FIG. 3, a resistor 20 (e.g., conductor) is formed on the layer 16, using conventional methods. By way of one non-limiting illustration, a conventional PECVD or high density PECVD deposition process may be used to form the resistor 20. This process includes depositing polysilicon (poly) on the layer 16, and then etching the poly using conventional methods, e.g., reactive ion etching (RIE). An annealing process may then be performed to activate the resistor 20. In another implementation, a doped poly deposition process may be utilized, in which case the annealing step may not be necessary. However, annealing may still be performed to passivate the one or more contact studs 18. The STI 12 is substantial aligned with the resistor 20 to effectively increase a distance between the resistor and the substrate 10.

The resistor 20 may additionally include a nitride layer, which may be required for manufacturing processes depending on the selectivity of the RIE used in subsequent processing steps. For example, the nitride layer may act as a stop during the RIE process, forming the resistor shown in FIG. 1.

FIG. 4 shows the formation of an Ml Inter Level Dielectric (ILD) layer 22. In this process, a dielectric material is used to electrically separate closely spaced interconnect lines arranged in several levels. In implementation, the ILD layer 22 has a low dielectric constant k (e.g., close to 1 as possible) to minimize capacitive coupling (“cross talk”) between adjacent metal lines.

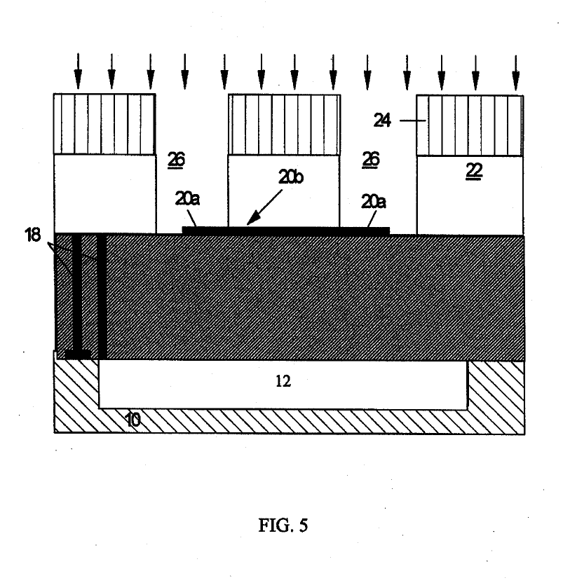

FIG. 5 shows the self-aligning process for resistor end implant. As represented in FIG. 5, a photoresist mask 24 is deposited over the ILD layer 22. In conventional processes, the photoresist mask 24 is exposed and the ILD layer 22 is then etched using conventional methods such as, for example, reactive ion etching (RIE) to form trenches 26. In this way, the trenches 26 are aligned with the ends 20a of the resistor 20.

In further processing steps represented in FIG. 5, the ends 20a of the resistor 20 are implanted with dopants, using the self-aligned trenches 26. In one embodiment, the implantation process takes place at the solid solubility limit of the poly resistor 20 or other resistor material. The implantation of the dopant may occur in the range of 8e¹⁵ to an upper limit of 2e¹⁶ atoms/cm², using conventional dopants. For example, the dopants may include, for n-type, Arsenic, Phosphorous or Antimony; whereas, the dopants may include, for p-type, Boron, Indium or BF₂.

In the processes represented in FIG. 5, the ILD layer 22 and photoresist 24 will prevent (block) the dopants from penetrating the middle 20b of the resistor 20. In this embodiment, the photoresist 24 may be removed after the implantation process. However, the photo-resist 24 may be removed prior to the implantation process, since the ILD layer 22 will be sufficient, alone, to block the dopants from penetrating the middle 20b of the resistor 20.

The ILD layer 22 and/or photoresist 24 will ensure that the middle 20b of the resistor 20 remains in a low-doped state thus maintaining a high resistance value. On the other hand, the trenches 26 allow the dopants to penetrate the ends 20a of the resistor 20 which, in turn, become highly doped, e.g., have a concentration higher than that of the middle 20b of the resistor. This highly doped state results in improved ohmic contact.

As in all of the embodiments, the resistor doping is performed during BEOL processes, which utilize an anneal in the range of 300° C. to 600° C. These BEOL processes are operations performed on the semiconductor wafer in the course of device manufacturing following first metallization. It is well understood by those of skill in the art, that the temperature ranges of BEOL processes, which are significantly lower than implemented in FEOL processes, will not affect the dopants or resulting structure. For example, the BEOL process temperatures will not cause deactivation and activation fluctuations in the polysilicon resistor. Nor with the thermal cycles affect the morphology of the polysilicon film, thus resulting in a substantially constant resistance value of the resistor (as compared to the fluctuations associated with the thermal cycles of FEOL processes).

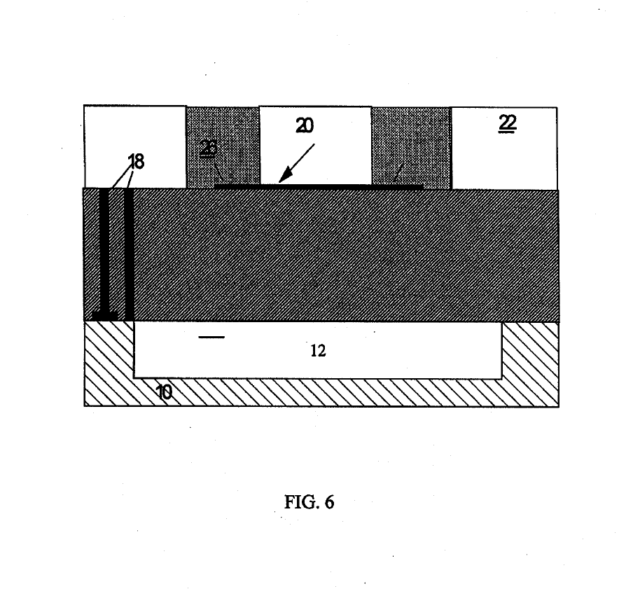

FIG. 6 shows a metal fill process. For example, the trenches 26 may be lined with Ta, TaN or other refractory metals and filled with copper using a damascene process. The resultant structure is then planarized, leaving the metal within the trenches 26.

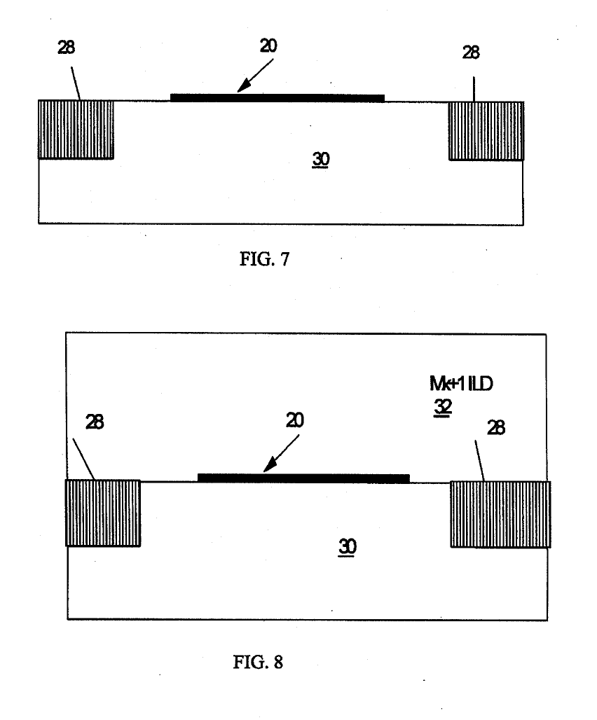

FIG. 7 shows a beginning structure in accordance with an embodiment of the invention. In this structure, metal lines 28 are formed in an underlying layer 30 such as an ILD. A resistor 20 is formed on the layer 30, similar to the process steps described with reference to FIG. 3. By way of non-limiting illustration, this process may include performing a conventional PECVD or high density PECVD deposition process with a subsequent etching and annealing process, or utilizing a doped poly deposition process. The resistor may additionally include a nitride layer, which may be required for manufacturing processes depending on the selectivity of the RIE used in subsequent processing steps.

FIG. 8 shows the formation of an Mx+1 ILD layer 32. In implementation, the ILD layer 32 has a low dielectric constant k (e.g., close to 1 as possible) to minimize capacitive coupling (“cross talk”) between adjacent metal lines.

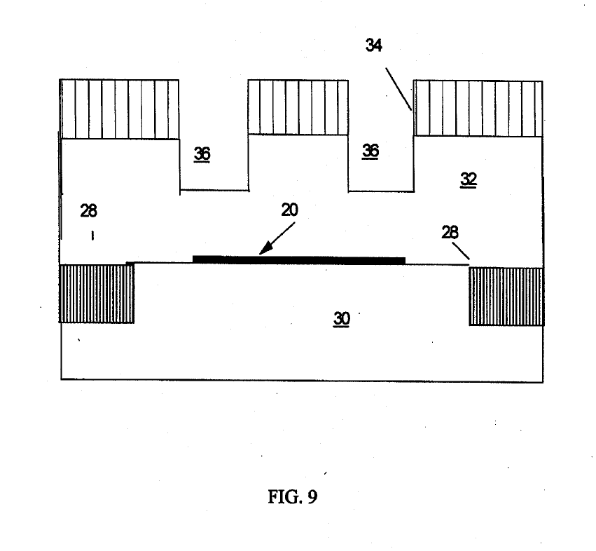

FIG. 9 shows steps in the self-aligning process for resistor end implant. As represented in FIG. 9, a photoresist mask 34 is deposited over the ILD layer 32. Then, the photoresist mask 34 is exposed in order to etch the ILD layer 32. The ILD layer 32 is etched using conventional methods such as, for example, reactive ion etching (RIE) to form trenches 36.

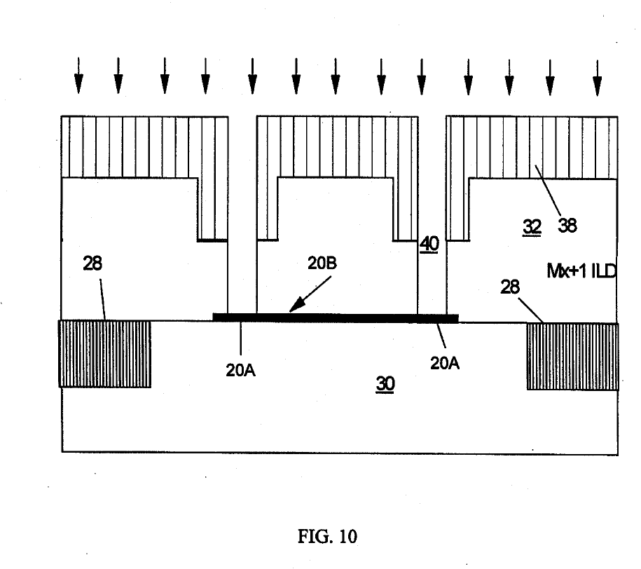

In further processing steps represented in FIG. 10, another photoresist mask 38 is deposited in the trenches 36 after the removal of initial photoresist mask 34. Then, the photoresist mask 38 is exposed, and the exposed portions of the ILD layer 32 are etched to the ends 20a of the resistor 20. The etching process may be performed using conventional methods such as, for example, reactive ion etching (RIE) to form vias 40.

The ends 20a of the resistor 20 are implanted with dopants, using the self-aligned vias 40. In one embodiment, the implantation process takes place at the solid solubility limit of the poly resistor 20 or other resistor material. As with the previous embodiment, the implantation of the dopant may occur in the range of 8e¹⁵ to an upper limit of 2e¹⁶ atoms/cm², using conventional dopants.

In the processes represented in FIG. 10, the ILD layer 32 and photoresist will prevent (block) the dopants from penetrating the middle 20b of the resistor 20. As previously discussed, the photoresist may be removed prior to or after the implantation process, since the ILD layer 32 will be sufficient, alone, to block the dopants from penetrating the middle 20b of the resistor 20. Also, the ILD layer 32 and/or photoresist will ensure that the middle 20b of the resistor 20 remains in a low-doped state thus maintaining a high resistance value. On the other hand, the vias 40 allow the dopants to penetrate the ends 20a of the resistor 20 which, in turn, become highly doped. This highly doped state results in improved ohmic contact.

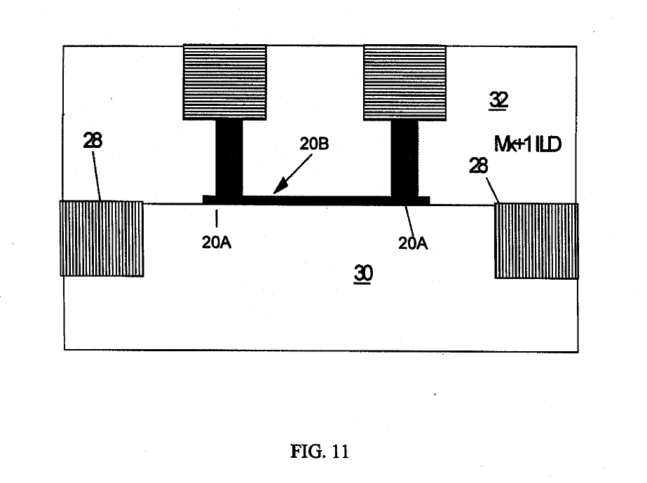

FIG. 11 shows a metal fill process. In this process, for example, the vias 40 and trenches 36 may be lined with Ta, TaN or other refractory metals and filled with copper using a damascene process. The resultant structure is then planarized, leaving the metal within the vias 40 and trenches 36.

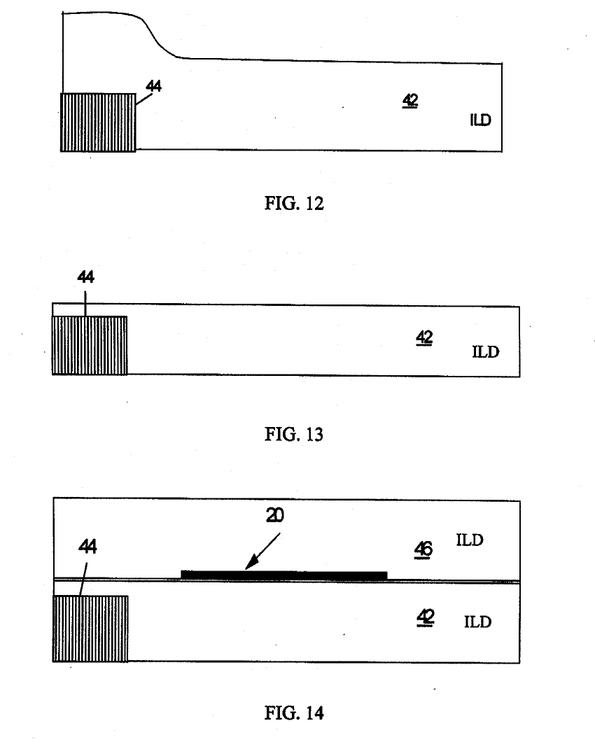

FIG. 12 shows a partial beginning structure in accordance with another embodiment of the invention. In this structure, a conformal ILD layer 42 is deposited over a metal line 44. In FIG. 13, the ILD layer 42 is planarized using, for example, a conventional CMP process.

In FIG. 14, the resistor 20 is formed on the ILD layer 44. As previously discussed, the formation of the resistor 20 may be provided in any conventional manner such as, for example, performing a conventional PCVD or high density PCVD deposition process or a doped poly deposition process. The resistor may additionally include a nitride layer, which may be required for manufacturing processes depending on the selectivity of the RIE used in subsequent processing steps. FIG. 14 also shows the formation of an additional ILD layer 46, with planarization process.

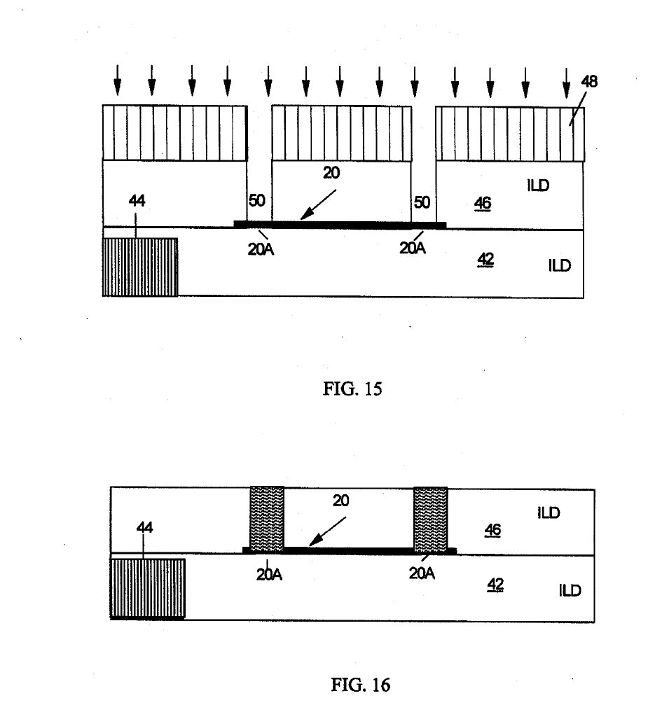

FIG. 15 shows the self-aligning process for resistor end implant. As represented in FIG. 15, a photoresist mask 48 is deposited over the ILD layer 46, which is then exposed in order to etch the ILD layer 46. The ILD layer 46 is then etched using conventional methods such as, for example, RIE to form vias 50, aligned with the ends 20a of the resistor 20.

In further processing steps, the ends 20a of the resistor 20 are implanted with dopants, using the self-aligned vias 50. In one embodiment, the implantation process takes place at the solid solubility limit of the poly resistor 20 or other resistor material. Again, in one embodiment, the implantation of the dopant may occur in the range of 8e¹⁵ to an upper limit of 2e¹⁶ atoms/cm², using conventional dopants.

In the processes represented in FIG. 15, the ILD layer 46 and photoresist 48 will prevent (block) the dopants from penetrating the middle 20b of the resistor 20. In this embodiment, the photo-resist 26 may be removed before (or after) the implantation process, since the ILD layer 46 will be sufficient, alone, to block the dopants from penetrating the middle 20b of the resistor 20.

As noted in the previous embodiments, the ILD layer 46 and/or photoresist 48 will ensure that the middle 20b of the resistor 20 remains in a low-doped state thus maintaining a high resistance value. On the other hand, the vias 50 allow the dopants to penetrate the ends 20a of the resistor 20 which, in turn, become highly doped, e.g., have a concentration higher than that of the middle 20b of the resistor. This highly doped states result in improved ohmic contact.

FIG. 16 shows a metal fill process using, for example, Aluminum. The vias 50 may also be lined with Ti, TiN or other refractory metals and filled with Tungsten using a damascene process. The resultant structure is then planarized, leaving the metal within the vias 50.

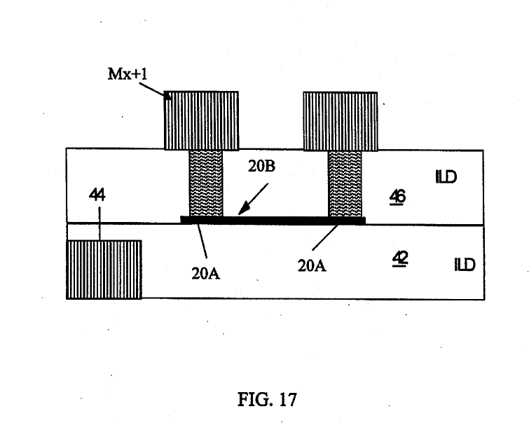

FIG. 17 shows the formation of metal lines 52 connecting to the metal within the vias 50. This metal provides a contact between the resistor 20 and the upper metal lines 52.

While the invention has been described in terms of exemplary embodiments, those skilled in the art will recognize that the invention can be practiced with modifications and in the spirit and scope of the appended claims.

What is claimed is:

1. A method comprising:
forming a dielectric layer on a substrate having a wiring layer;
forming a resistor on the dielectric layer;
patterning a second dielectric layer formed over the resistor to expose edge portions of the resistor;
doping the edge portions of the resistor through the openings; and
forming a contact in the openings.

2. The method of claim 1, further comprising providing a shallow trench isolation structure to effectively increase a distance between the resistor and the substrate.

3. The method of claim 1, wherein the resistor is formed by a PECVD or high density PECVD deposition process and a subsequent annealing process, or a doped poly deposition process.

4. The method of claim 1, further comprising depositing a nitride layer over the resistor.

5. The method of claim 1, further comprising forming at least one metal layer in the dielectric layer, prior to the formation of the resistor.

6. The method of claim 1, wherein the second dielectric layer blocks dopant implantation in a middle portion of the resistor.

7. The method of claim 1, wherein the patterning step includes etching a trench in an upper layer of the dielectric and etching a via in a lower layer of the dielectric, in alignment with the trench, to expose the edge portions of the resistor.

8. The method of claim 7, further comprising filling the trench and the via with contact material.

9. The method of claim 1, wherein the dielectric layer prevents dopants from penetrating a middle of the resistor to ensure that the middle of the resistor maintains a high resistance value, and the doped edge portions become highly doped resulting in an ohmic contact.

10. The method of claim 1, wherein the dielectric layer is deposited over a metal level, and is planarized prior to the formation of the resistor.

11. The method of claim 10, further comprising etching vias into the dielectric layer to expose the edge portions of the resistor.

12. The method of claim 11, further comprising filling the vias with contact material to the resistor and forming an Mx+1 metal layer in contact with the contact material.

13. The method of claim 1, wherein the resistor is formed in a back end of line (BEOL) process at temperatures which do not cause deactivation and activation fluctuations or manipulate the morphology of resistor film.

14. A method comprising:
providing a substrate having at least a wiring level in a first dielectric layer;
forming a conductor layer on the first dielectric layer;
patterning the conductor layer to form end portions and a body portion;
forming a second dielectric layer over the patterned conductor layer;
forming openings in the second dielectric layer substantially aligned to the end portions, the openings exposing the end portions of the conductor layer;
forming an impurity region in each of the end portions through the openings; and
forming a contact in the openings coupled to the end portions to provide electrical connection to the wiring level.

15. The method of claim 14, wherein the step of forming the impurity region comprises ion implanting a dopant at a high concentration.

16. The method of claim 15, wherein the dopant is activated without requiring an anneal step.

17. The method of claim 14, wherein the high concentration is a solid solubility limit of the conductor layer.

18. The method of claim 14, wherein the conductor layer comprises polysilicon.

19. A structure, comprising:
a substrate having at least a wiring level formed in a first dielectric layer;
a resistor formed on the first dielectric having ends aligned with openings formed in a second dielectric layer, an impurity region being provided in each of the end portions having a higher dopant concentration than that of a middle portion of the resistor, the middle portion of the resistor maintains a high resistance value and the doped end portions are an ohmic contact; and
a contact in the openings coupled to the end portions provide electrical connection to a Mx+1 wiring level.

20. The structure of claim 19, further comprising an active device on the substrate connected to metal studs formed in the first dielectric layer.
